(19) United States
(12) Patent Application Publication
(10) Pub. No.: US 2026/0105968 A1
(43) Pub. Date: Apr. 16, 2026

(54) READ METHOD AND READ COMMAND FORMAT FOR FLASH MEMORY DEVICE

(71) Applicant: MACRONIX International Co., Ltd., Hsinchu (TW)

(72) Inventors: Shih-Chang Huang, Penghu County (TW); Han-Sung Chen, Hsinchu City (TW); Chin-Chieh Chang, Taichung City (TW)

(73) Assignee: MACRONIX International Co., Ltd., Hsinchu (TW)

(21) Appl. No.: 18/916,724

(22) Filed: Oct. 16, 2024

(51) Int. Cl. G11C 16/26; G11C 16/08

(52) U.S. Cl. CPC G11C 16/26; G11C 16/08

(57) ABSTRACT

A read method and a read command format for a flash memory device are provided. The read method includes: determining whether a block to be read is an open block based on a special code in a read command, wherein the open block has a written area and an unwritten area; when it determines the block is not the open block, during reading a selected word line, unselected word lines are applied with a first read pass bias set; when it determines the block is the open block, during reading the selected word line, unselected word lines in the written area are applied with a second read pass bias set and unselected word lines in the non-written area are applied with a third read pass bias set. The invention is suitable for three-dimensional NAND flash memory, and is provided with high capacity and high performance.

### BACKGROUND OF THE INVENTION

### Field of the Invention

The invention relates to a memory operation, and particularly, to a read method and a read command format for a flash memory.

### Description of Related Art

Generally, a 3D memory, such as a non-volatile memory flash memory, has a multi-layer structure (such as word line layers). Therefore, when a 3D memory is read, detailed layer compensation is required for read window. In addition, when the 3D memory is operated, the 3D memory generally has to be programmed first. Usually, when the 3D memory is programmed, each word line (layer) in a block is programmed one by one in a predetermined sequence. After the memory cells of each word line (layer) are programmed, the data written in the memory cells needs to be verified, which is the so-called program verification. During the verification, verification voltages are applied to the word line, and a verification pass voltage Vpass_pv is applied to other word lines. At this time, a corresponding bit line verification voltage Vblc_pv is also applied to the corresponding bit line to verify whether the memory cells are correctly programmed. In addition, memory cells that are not programmed are in a low-threshold voltage state.

Next, when reading the memory block in which data is written, read voltages are applied to the word line and the bit line to be read. In addition, since data is written into the memory block, each of the memory cells may be in a low-threshold voltage state or a high-threshold voltage state. Therefore, when a first word line read pass voltage Vpass_rd is applied to the word lines that are not to be read, the first word line read pass voltage Vpass_rd needs a larger voltage to turn on the memory cells that are not to be read.

As described above, the verification pass voltage Vpass_pv used during programming and the first word line read pass voltage Vpass_rd used during reading are different. In other words, the bias settings of the pass voltages for the word lines/bit lines used during programming and reading are different. However, applying too large voltage may change the threshold voltage of the memory cell.

Therefore, when the memory block is an open block, since a portion of the open block is not written with data, those memory cells not written with data are in a low-threshold voltage state. In this case, if the normal read bias setting is still used, for example, the first word line read pass voltage Vpass_rd is still used to apply to the unselected word lines, data read errors may occur and additionally read interference may occur.

Therefore, how to avoid read errors and read interference when an open block is read is a topic.

### SUMMARY OF THE INVENTION

In view of the above description, according to an embodiment of the invention, a read method for a flash memory device is provided. The read method includes a read method for a flash memory device, wherein the flash memory device includes a plurality of blocks, and the read method includes: receiving a read command to read at least one block of the plurality of blocks, wherein the read command is appended with a special code and a final written word line address; determining whether the at least one block is an open block based on the special code of the read command, wherein the open block has a written area and an unwritten area; during reading the at least one block, applying a first read pass bias set to a plurality of unselected word lines in the at least one block when it is determined that the at least one block is not the open block; and during reading the at least one block, applying a second read pass bias set to a plurality of unselected word lines in the written area of the at least one block and applying a third read pass bias set to a plurality of unselected word lines in the unwritten area when it is determined that the at least one block is the open block.

According to another embodiment of the invention, a read command format for a flash memory device is provided. The read command format includes: a special code used to specify whether each of a plurality of blocks in the flash memory device is an open block; a final written word line address used to specify an address of a final written word line in each of the plurality of blocks; and a read command specification in compliance with a standard format of the flash memory device, and the read command specification further includes a read command, a column address, a row address, and a read confirmation command sequentially.

Based on the above, when the open block of the flash memory is read, the word line read pass voltage applied to the unselected word lines in the unwritten area is set to be different from the word line read pass voltage applied to the unselected word lines in the written area, to reduce false readings and read interference. In addition, according to the position of the final written word line, the bit line read pass voltage of the bit line may be adjusted accordingly, which may further reduce misreading and read interference.

### BRIEF DESCRIPTION OF THE DRAWINGS

FIG. 1 shows a schematic diagram of an open block of a flash memory.

FIG. 2 is a schematic flowchart of a read method shown according to an embodiment of the invention.

FIG. 3A and FIG. 3B are schematic diagrams of a read method for a flash memory according to an embodiment of the invention.

FIG. 4A to FIG. 4C show a read command format for an existing flash memory.

FIG. 5A to FIG. 5D are a read command format for a flash memory according to an embodiment of the invention.

FIG. 6 is a flowchart of determining a bit line read pass voltage according to an embodiment of the invention.

FIG. 7 is a schematic block diagram of determining a bit line read pass voltage according to an embodiment of the invention.

### DESCRIPTION OF THE EMBODIMENTS

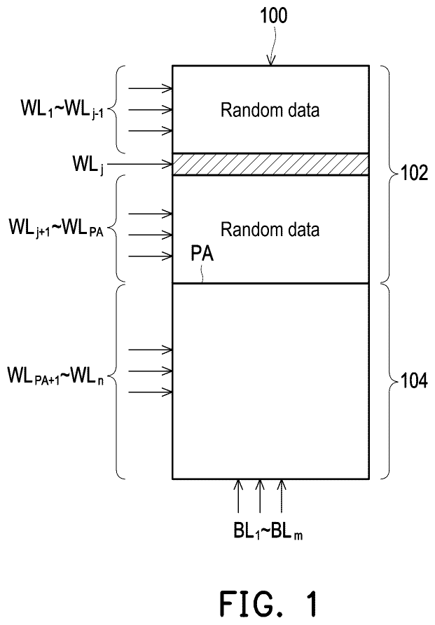

FIG. 1 shows a schematic diagram of an open block of a flash memory. The flash memory comprises a memory array. The memory array comprises a plurality of blocks, and each of the blocks may be addressed by a plurality of word lines (WL₁ to WLₙ in this example, n is an integer) and bit lines (BL₁ to BLₘ, m is an integer). As shown in FIG. 1, a schematic diagram of one open block is illustrated, the so-called open block here means that when programming a block 100, data is not written into the entire block 100, and a portion of the block is not written with data. At this time, this block 100 is called an open block. In the following description, without affecting understanding, the reference number 100 may refer to a block, especially an open block.

As shown in FIG. 1, the open block 100 includes a written area 102 and an unwritten area 104. When the block 100 of the flash memory is programmed, the word lines WL₁ to WLₙ are sequentially programmed one by one. For example, in a 3D stacked flash memory, this sequence may be from top to bottom or bottom to top. Therefore, the unwritten area 104 generally immediately follows the written area 102. In addition, the symbol PA in FIG. 1 represents the address of the final written word line WL_{PA}, that is, final written word line address PA, and that is, the open block 100 is only written to the memory cells on the word lines WL₁˜WL_{PA}.

In addition, the memory cells in the written area 102 are all already programmed, so random data is stored therein. That is, the memory cells may be in a low-threshold voltage state or a high-threshold voltage state, or there may exist multiple threshold voltage states. In addition, the memory cells in the unwritten block 104 are all not yet programmed, so the memory cells are all in a low-threshold voltage state. In the following examples, reading the data of the memory cells on the word line WLⱼ is taken as an example, that is, the word line WLⱼ is selected as the target for the read operation. The other word lines WL₁ to WLⱼ₋₁, WLⱼ₊₁ to WL_{PA}, and WL_{PA+1} to WLₙ are not the target to be read, that is, the unselected word lines.

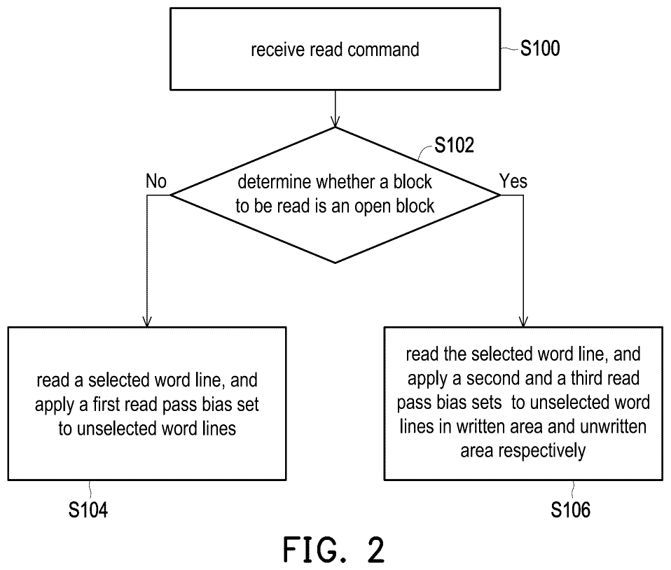

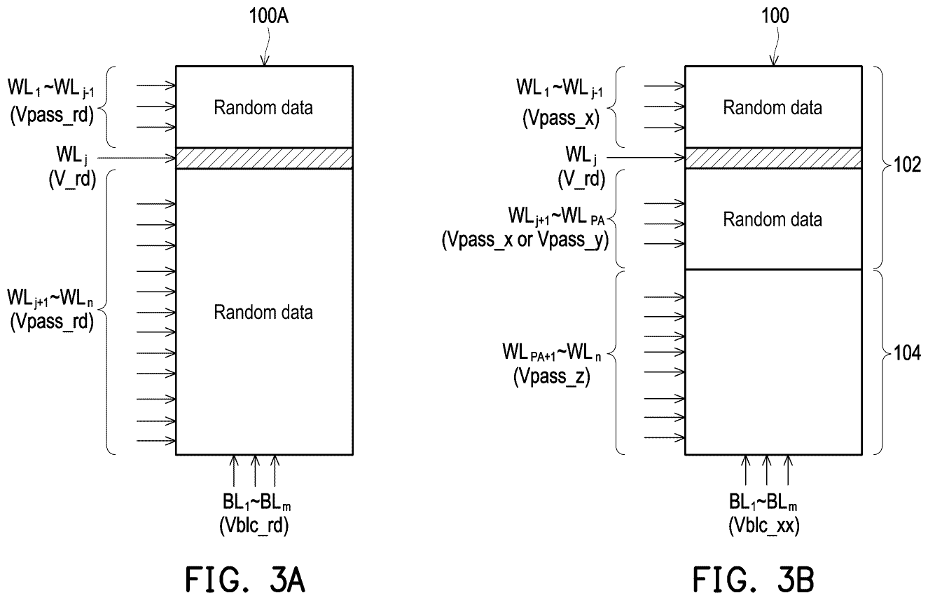

FIG. 2 is a schematic flowchart of a read method according to an embodiment of the invention. FIG. 3A and FIG. 3B are schematic diagrams of a read method for a flash memory according to an embodiment of the invention. Hereinafter, a read method for an open block in a flash memory according to an embodiment of the invention is described with reference to FIG. 2 and FIG. 3A and FIG. 3B.

According to an embodiment of the invention, as shown in FIG. 2, in step S100, when a certain block of the memory array of the flash memory is to be read, the controller of the flash memory sends a read command to the memory array to select at least one of the plurality of word lines of the block (such as the word line WLⱼ shown in FIG. 3A or FIG. 3B), i.e., a selected word line, and the other word lines are unselected word lines. In addition, according to an embodiment of the invention, the read command has a specific read command format, which will be described in detail later. This read command format is provided with a special code and a final written word line address PA in the read command specification. The read command specification is in compliance with the standard specification of the current flash memory. The final written word line indicates the final written word line address PA in a block (as shown in FIG. 3B).

Next, in step S102, based on the special code of the read command, it is determined whether the block to be read is an open block. Therefore, when the read command is received, it may be known through the special code that the block is not completely written, and therefore may be determined to be an open block. Furthermore, by using the final written word line address PA, it may also be known that the unwritten area 104 begins from which word line of the open block 100. In this case, it is assumed that the programming sequence is from top to bottom (and vice versa), then the portion of the open block 100 shown in FIG. 3B before and includes the word line WL_{PA} (that is, corresponding to word lines WL₁ to WL_{PA}) is the written area 102. The memory cells thereof are all already programmed, so the state of the memory cells may be a low-threshold voltage state or a high-threshold voltage state, which is random data. In addition, as shown in FIG. 3B, the portion of the open block 100 after the word line WL_{PA} (and the corresponding word lines WL_{PA+1} to WLₙ) is the unwritten area 104, and the memory cells thereof are all not programmed. Therefore, the state of the memory cells is a low-threshold voltage state.

Next, in step S102, when it is determined that the block to be read is a non-open block 100A as shown in FIG. 3A, step S104 is executed. In step S104, all the memory cells in the block have been programmed, so the current read method may be adopted to read the selected word line WLⱼ. Specifically, a word line read voltage V_rd is applied to the selected word line WLⱼ and an appropriate bit line read voltage Vbl is applied to the selected bit line to perform reading. At the same time, a first read pass bias set is applied to the unselected word lines WL₁ to WLⱼ₋₁ and WLⱼ₊₁ to WLₙ in the block 100A. The first read pass bias set includes a first word line read pass voltage Vpass_rd and a first bit line read pass voltage Vblc_rd, as shown in FIG. 3A. In this way, memory cells on unselected word lines are turned on.

Moreover, in step S102, when it is determined that the block to be read is the open block 100 as shown in FIG. 3B, step S106 is executed. As mentioned above, the written area 102 refers to the area before and includes the final written word line WL_{PA} of the open block 100, and the unwritten area 104 refers to the area after the final written word line WL_{PA} of the open block 100. According to an embodiment of the invention, when the selected word line WLⱼ is read, the setting of the read pass voltage for the unselected word lines WL₁ to WLⱼ₋₁ and WLⱼ₊₁ to WL_{PA} in the written block 102 and the setting of the read pass voltage for the unselected word lines WL_{PA+1} to WLₙ in the unwritten block 104 are different.

In other words, when the open block 100 is read, for the method of reading the selected word line, the application method of the read voltage thereof is the same as the current method, that is, the word line read voltage V_rd is applied to the selected word line WLⱼ and the appropriate bit line read voltage Vbl is applied to the selected bit line. However, the setting method of the read pass voltage for the unselected word lines is different from the current method.

As shown in FIG. 3B, a second read pass bias set is applied to the unselected word lines WL₁ to WLⱼ₋₁ and WLⱼ₊₁ to WL_{PA} in the written area 102 of the open block 100. According to an embodiment of the invention, the second read pass bias set may include a second word line read pass voltage Vpass_x and a second bit line read pass voltage Vblc_xx. In addition, a third read pass bias set is applied to the unselected word lines WL_{PA+1} to WLₙ in the unwritten area 104 of the block 100. Here, the third read pass bias set may include a third word line read pass voltage Vpass_z and the second bit line read pass voltage Vblc_xx.

According to an embodiment of the invention, the third word line read pass voltage Vpass_z of the third read pass bias set is different from the second word line read pass voltage Vpass_x of the second read pass bias set. As an example, since the memory cells in the unwritten area 104 are all in a low-threshold voltage state, the third word line read pass voltage Vpass_z applied to the unselected word lines WL_{PA+1} to WLₙ may be set to be less than the second word line read pass voltage Vpass_x applied to the unselected word lines WL₁ to WLⱼ₋₁ and WLⱼ₊₁ to WL_{PA}.

Furthermore, in the above example, when the selected word line WLⱼ is read, the same second read pass bias set is applied to the unselected word lines WL₁ to WLⱼ₋₁ and WLⱼ₊₁ to WL_{PA} in the written area 102 of the open block 100, but the invention is not limited thereto. As one example, the word line read pass voltage applied to the unselected word lines WL₁ to WLⱼ₋₁ and WLⱼ₊₁ to WL_{PA} in the written area 102 may be appropriately adjusted according to the position (number) of the word lines. For example, in the example of FIG. 3B, the word line read pass voltage Vpass_x may be applied to the unselected word lines WL₁ to WLⱼ₋₁, but the word line read pass voltage Vpass_y may be applied to the unselected word lines WLⱼ₊₁ to WL_{PA}. In addition, in this example, the unselected word lines WL₁ to WLⱼ₋₁ and WLⱼ₊₁ to WL_{PA} in the written area 102 are all divided into two sections, and different word line read pass voltages Vpass_x and Vpass_y are applied thereto respectively. However, the unselected word lines WL1 to WLⱼ₋₁ and WLⱼ₊₁ to WL_{PA} may also be further divided into more sections to apply different word line read pass voltages.

Furthermore, according to an embodiment of the invention, the second word line read pass voltage Vpass_x (and/or Vpass_y) of the second read pass bias set applied to the unselected word lines WL₁ to WLⱼ₋₁ and WLⱼ₊₁ to WL_{PA} in the written area 102 may adopt the first word line read pass voltage Vpass_rd in the same manner as in the current method. Of course, the second word line read pass voltage Vpass_x (and/or Vpass_y) may also be set to be different from the first word line read pass voltage Vpass_rd.

As described above, when the open block 100 is read, the third word line read pass voltage Vpass_z applied to the unselected word lines WL_{PA+1} to WLₙ of the unwritten area 104 is different from the second word line read pass voltage Vpass_x (and/or Vpass_y) applied to the unselected word lines WL₁ to WLⱼ₋₁ and WLⱼ₊₁ to WL_{PA} of the written area 102. Therefore, the word line read pass voltage may be fine-tuned more appropriately, and data misreading and read interference may be further prevented when reading the selected word line WLⱼ.

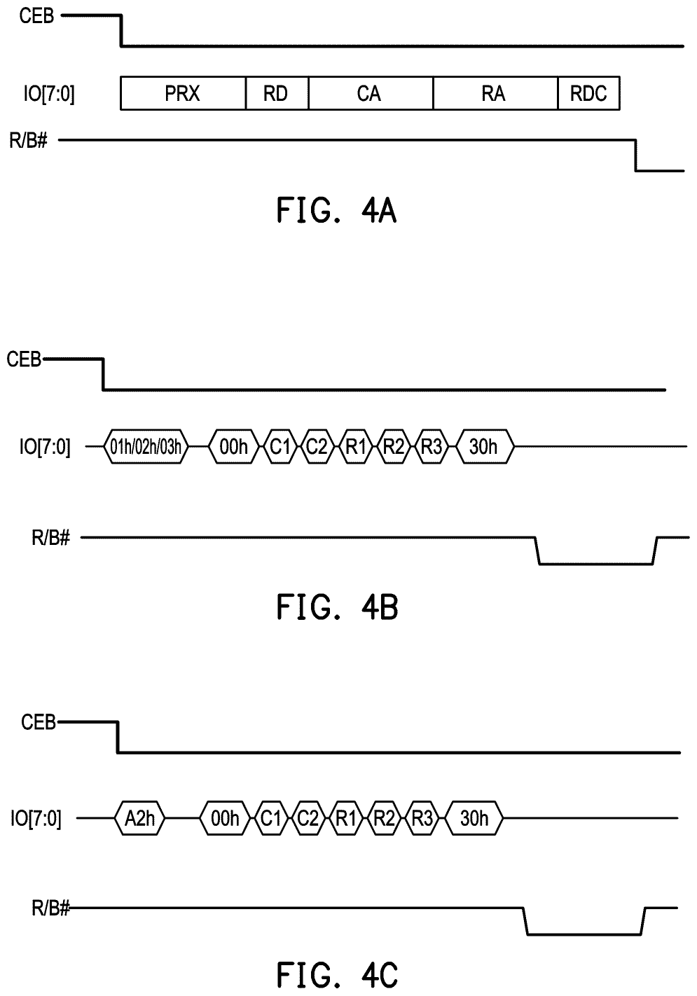

FIG. 4A to FIG. 4C show a read command format for the current flash memory. As shown in FIG. 4A, the read command format for the current flash memory comprises a prefix PRX, a read command code RD, addresses CA and RA, and a read confirmation command RDC. After a chip enable signal CEB becomes the low level, the command is sent at I/O port IO[7:0]. According to the flash memory specification, the read command code RD is, for example, 00h, and the read confirmation command RDC is, for example, 30h, indicating that the transmission of the read command code RD and the read addresses CA and RA thereof are completed. After a ready/busy signal R/B # becomes the low level, the flash memory sends data according to the read command. The address may comprise the column address CA and the row address RA. In FIG. 4B, the prefix PRX of the read command format may be set to 01h02h03h, indicating the memory cell to be read is a triple level cell (TLC). After the read command code 00h is sent, column addresses C1 and C2 and row addresses R1 and R2, R3, etc. of the memory cells to be read are immediately sent. In FIG. 4C, by setting the prefix PRX to A2h, it indicates the memory cell to be read is a single level cell (SLC). The prefix PRX may be used to set different memory configurations, etc.

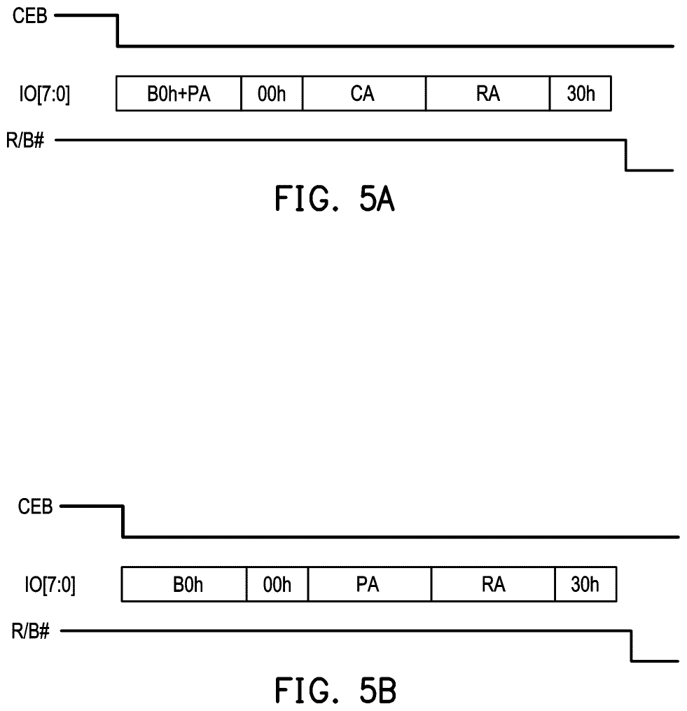

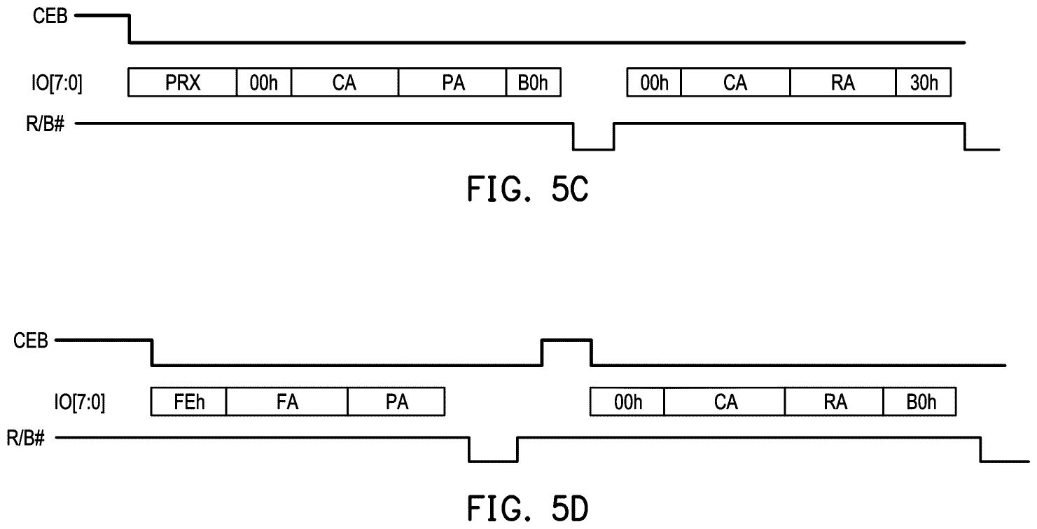

According to an embodiment of the invention, a read command format is provided, whereby it may be determined whether the block to be read is an open block. FIG. 5A to FIG. 5D illustrate various read command formats according to embodiments of the invention. The basic concept of this read command format design is to add the special code (such as B0h) and the final written word line address PA to the read command specification. The read command format shown in FIG. 4A that includes the prefix PRX, the read command code RD, the addresses CA and RA, and the read confirmation command RDC. The attachment method for the special code and the final written word line address PA may be discussed with the customer and then determined. Here are a few possible arrangements.

As shown in FIG. 5A, the simplest way is to append the special code (such as B0h, of course other values may also be used) and the final written word line address PA to the read command specification. That is, the special code B0h and the final written word line address PA followed by the special code B0h as a whole are added before the read command code RD (such as 00h). In addition, a prefix PRX may also be added before the special code B0h.

In the example shown in FIG. 5B, since reading one block is usually reading the entire page, the column address CA is usually rarely used. Therefore, the final written word line address PA may replace the column address CA in the standard read command specification. In addition, the special code B0h remains before the read command code RD (such as 00h). In addition, a prefix PRX may also be added before the special code B0h.

In the example shown in FIG. 5C, a command format for a multiplane block is shown. In this example, the read command format includes a first portion and a second portion. The first portion sequentially includes the prefix PRX, the read command code 00h, the column address CA, the final written word line address PA, and the special code B0h. The second portion includes the read command code 00h, the column address CA, the row address RA, and the read confirmation command 30h in sequence, which is the above standard read command specification.

The example given above simply attaches the special code B0h and the final written word line address PA to the standard read command specification. The following example further uses another command of the flash memory. There are also some personalized functions in the standard specification of the flash memory. Using the so-called set feature command in the standard specification, expansion may be made to implement self-defined features. Therefore, the present embodiment uses the set feature command to define the open block.

In the example of FIG. 5D, the read command format further includes a set feature value portion (left side of the figure) and a read command specification (right side of the figure). The set feature value portion includes in sequence a set feature command FEh, a feature value FA, and the final written word line address PA. In addition, the read command specification also includes the read command code 00h, the column address CA, the row address RA, and the special code B0h in sequence. That is, the read confirmation command 30h of the read command specification (that is, the second portion) of FIG. 5C is replaced with the special code B0h.

In addition, when there is one or more blocks to be read, the read command format may include a plurality of sets of feature values/final written line addresses, such as B0h/PA0, B1h/PA1, . . . , etc., to distinguish whether different blocks are open blocks and the addresses of the respective final written word lines.

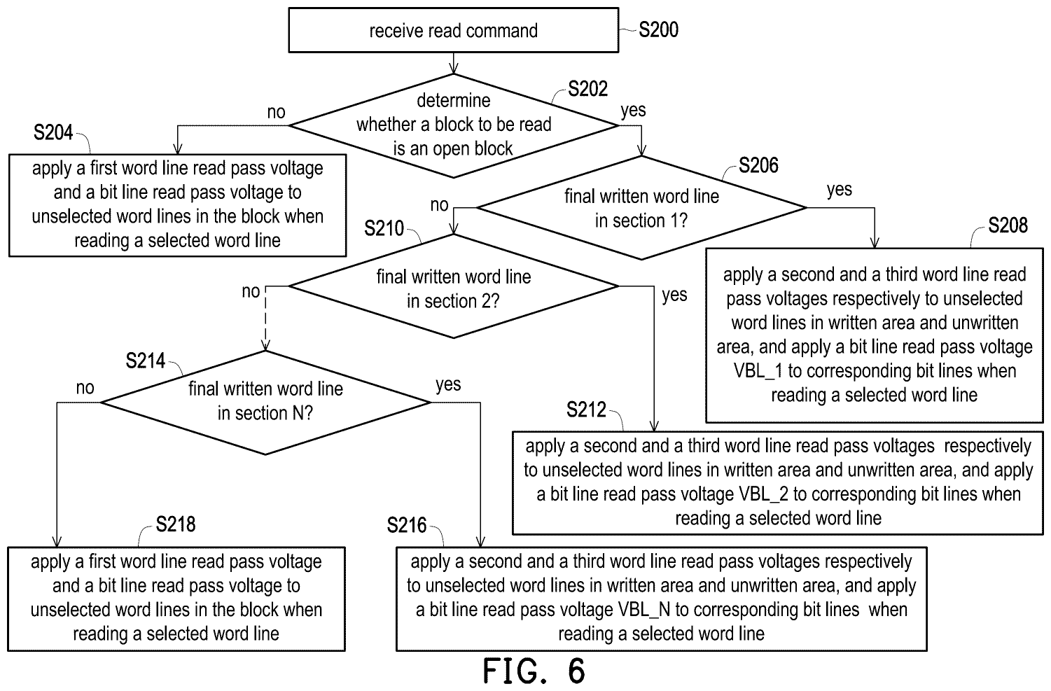

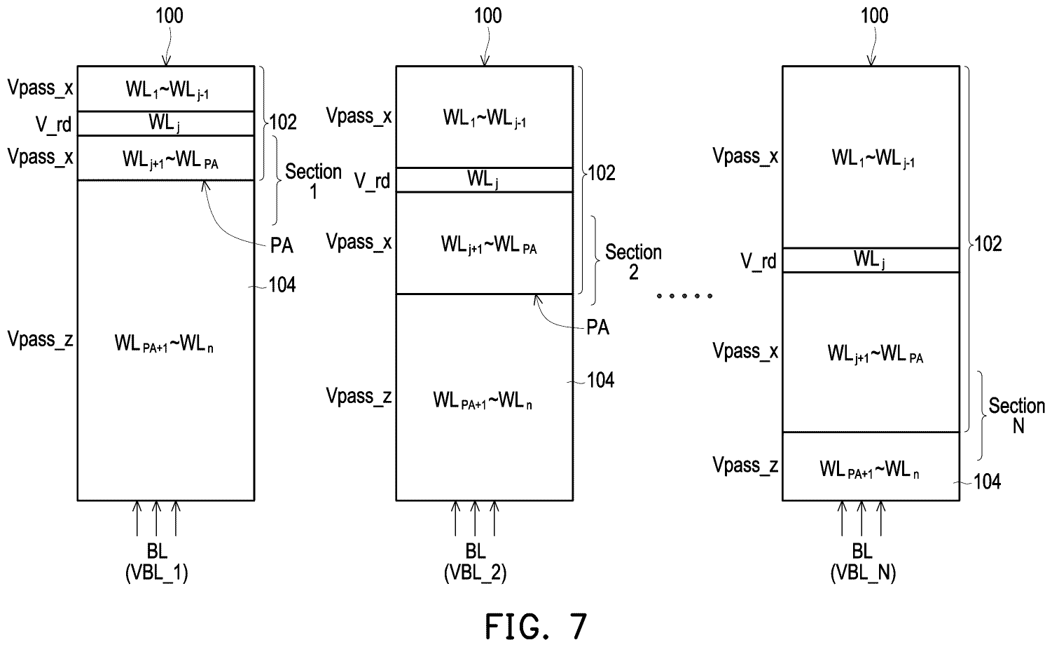

FIG. 6 is a flowchart of determining a bit line read pass voltage according to an embodiment of the invention. FIG. 7 is a schematic block diagram of determining a bit line read pass voltage according to an embodiment of the invention. As shown in FIG. 7, the configuration example of the open block 100 here is the same as that of the above FIG. 3B, so the same portions are as provided in the above description, and repeated portions are omitted here. Here, the open block 100 may be further divided into a plurality of sections, such as section 1, section 2, . . . , section N, wherein N is an integer. In addition, the final written word line address PA may be any area of the located in section 1, section 2, . . . , section N. When reading the selected word line WLⱼ, the word line read voltage V_rd is applied to the selected word line WLⱼ, the second word line read pass voltage Vpass_x (and/or Vpass_y, as detailed above) is applied to the unselected word lines WL₁ to WLⱼ₋₁ and WLⱼ₊₁ to WL_{PA} of the written area 102, and the third word line read pass voltage Vpass_z is applied to the unselected word lines WL_{PA+1} to WLₙ of the unwritten area 104.

Any one of the bit line read pass voltages VBLx (x=1 to N, N is an integer) is applied to the bit lines of the corresponding unselected word lines WL₁ to WLⱼ₋₁, WLⱼ₊₁ to WL_{PA}, and WL_{PA+1} to WLₙ. That is, the bit line read pass voltage VBLx is determined according to which section of the sections 1 to N the final written word line WL_{PA} is located in. Detailed description is given below with reference to FIG. 6.

As shown in FIG. 6, in step S200, a read command is received, and the read command is attached with the special code (such as B0h) and the final written word line address PA. In step S202, it is determined whether the block to be read is an open block based on the special code attached to the read command.

Next, in step S202, when it is determined that the block to be read is not an open block, step S204 is executed. In step S204, the word line read voltage V_rd is applied to the selected word line WLⱼ and the appropriate bit line read voltage Vbl is applied to the selected bit line to perform reading. At the same time, a first read pass bias set is applied to the unselected word lines WL₁ to WLⱼ₋₁ and WLⱼ₊₁ to WLₙ in the block, and the first read pass bias set includes the first word line read pass voltage Vpass_rd and the first bit line read pass voltage Vblc_rd.

In addition, in step S202, when it is determined that the block to be read is the open block 100, step S206 is executed to further determine whether the final written word line WL_{PA} is in the section 1. If the final written word line WL_{PA} is in the section 1, step S208 is executed. In step S208, when the selected word line WLⱼ is read, the second word line read pass voltage Vpass_x (and/or Vpass_y) is applied to the unselected word lines WL₁ to WLⱼ₋₁ and WLⱼ₊₁ to WL_{PA} of the written area 102, and the third word line read pass voltage Vpass_z is applied to the unselected word lines WL_{PA+1} to WLₙ of the unwritten area 104. In addition, a bit line read pass voltage VBL_1 is applied to the bit lines corresponding to the unselected word lines.

In step S206, if it is determined that the final written word line WL_{PA} is not in the section 1, step S210 is executed. In step S210, it is further determined whether the final written word line WL_{PA} is in the section 2. If the final written word line WL_{PA} is in the section 2, step S212 is executed. In step S212, when the selected word line WLⱼ is read, the second word line read pass voltage Vpass_x (and/or Vpass_y) is applied to the unselected word lines WL₁ to WLⱼ₋₁ and WLⱼ₊₁ to WL_{PA} of the written area 102, and the third word line read pass voltage Vpass_z is applied to the unselected word lines WL_{PA+1} to WLₙ of the unwritten area 104. In addition, a bit line read pass voltage VBL_2 is applied to the bit lines corresponding to the unselected word lines.

The process of determining which section the final written word line WL_{PA} is in continues until it is determined whether the final written word line WL_{PA} is in the section N. As in step S210, if it is determined that the final written word line WL_{PA} is not in the section 2, step S214 is executed. In step S214, it is further determined whether the final written word line WL_{PA} is in the section N. If the final written word line WL_{PA} is in the section N, step S216 is executed. In step S216, when the selected word line WLⱼ is read, the second word line read pass voltage Vpass_x (and/or Vpass_y) is applied to the unselected word lines WL₁ to WLⱼ₋₁ and WLⱼ₊₁ to WL_{PA} of the written area 102, and the third word line read pass voltage Vpass_z is applied to the unselected word lines WL_{PA+1} to WLₙ of the unwritten area 104. In addition, a bit line read pass voltage VBL_N is applied to the bit lines corresponding to the unselected word lines.

In step S214, if it is determined that the final written word line WL_{PA} is not in the section N, step S218 is executed. In step S218, when the selected word line WLⱼ is read, the first word line read pass voltage Vpass_rd and the first bit line read pass voltage Vblc_rd are applied to the unselected word lines WL₁ to WLⱼ₋₁ and WLⱼ₊₁ to WLₙ in the block.

When the open block is read, since the resistance of the memory cells in the low-threshold voltage state of the unwritten area 104 is different from the resistance of the memory cells in the high-threshold voltage state, the amount of memory cells in the low-threshold voltage state of the unwritten area 104 may be further determined by the final written word line address PA. Therefore, the bit line read pass voltage VBL_N applied to the bit line may be further adjusted correspondingly according to which section the final written word line WL_{PA} is located in. Thereby, misreading and read interference may be further reduced.

Based on the above, when the open block of the flash memory is read, the word line read pass voltage applied to the unselected word lines in the unwritten area is set to be different from the word line read pass voltage applied to the unselected word lines in the written area, so as to reduce misreading and read interference. In addition, according to the position of the final written word line, the bit line read pass voltage of the bit line may be adjusted accordingly, which may further reduce misreading and read interference.

What is claimed is:

1. A read method for a flash memory device having a plurality of blocks, comprising:
receiving a read command to read at least one block of the plurality of blocks, wherein the read command is appended with a special code and a final written word line address;
determining whether the at least one block is an open block based on the special code of the read command, wherein the open block has a written area and an unwritten area;
during reading the at least one block, applying a first read pass bias set to a plurality of unselected word lines in the at least one block when it is determined that the at least one block is not the open block; and
during reading the at least one block, applying a second read pass bias set to a plurality of unselected word lines in the written area of the at least one block and applying a third read pass bias set to a plurality of unselected word lines in the unwritten area when it is determined that the at least one block is the open block.

2. The read method for the flash memory device of claim 1, wherein the first read pass bias set comprises a first word line read pass voltage and a first bit line read pass voltage,
the second read pass bias set comprises a second word line read pass voltage and a second bit line read pass voltage.

3. The read method for the flash memory device of claim 1, wherein the second read pass bias set comprises a second word line read pass voltage and a second bit line read pass voltage,
the third read pass bias set comprises a third word line read pass voltage and the second bit line read pass voltage, and
wherein the third word line read pass voltage is different from the second word line read pass voltage.

4. The read method for the flash memory device of claim 2, wherein the second word line read pass voltage of the second read pass bias set is determined based on positions of the plurality of unselected word lines in the written area.

5. The read method for the flash memory device of claim 1, wherein the open block further comprises a plurality of sections,
bit line read pass voltages of the second read pass bias set and the third read pass bias set are determined according to which section of the plurality of sections the final written word line address is at.

6. The read method for the flash memory device of claim 1, wherein the read command has a read command format, the read command format is a read command specification plus the special code and the final written word line address, and the read command specification comprises a read command code, a column address, a row address, and a read confirmation command in sequence.

7. The read method for the flash memory device of claim 6, wherein the special code and the final written word line address are added before the read command specification.

8. The read method for the flash memory device of claim 7, wherein the read command format further comprises a prefix arranged before the special code.

9. The read method for the flash memory device of claim 6, wherein the special code is arranged before the read command of the read command specification, and the final written word line address replaces the column address.

10. The read method for the flash memory device of claim 9, wherein the read command format further comprises a prefix arranged before the special code.

11. The read method for the flash memory device of claim 1, wherein the read command has a read command format, and the read command format further comprises a first portion and a second portion,
the first portion comprises a prefix, a read command code, a column address, the final written word line address, and the special code in sequence, and
the second portion comprises the read command code, the column address, a row address, and a read confirmation command in sequence.

12. The read method for the flash memory device of claim 1, wherein the read command has a read command format, and the read command format further comprises a set feature value portion and a read command specification,
the set feature value portion comprises a set feature command, a feature value, and the final written word line address in sequence, and
the read command specification comprises a read command code, a column address, a row address, and the special code in sequence.

13. The read method for the flash memory device of claim 1, the read method further comprising applying a read voltage to a selected word line and applying a bit line voltage to a selected bit line to perform a reading.

14. A read command format for a flash memory device, comprising
a special code, used to specify whether each of a plurality of blocks in the flash memory device is an open block;
a final written word line address, used to specify an address of a final written word line in each of the plurality of blocks; and
a read command specification in compliance with a standard format of the flash memory device, and the read command specification further comprises a read command code, a column address, a row address, and a read confirmation command sequentially.

15. The read command format for the flash memory device of claim 14, wherein the special code and the final written word line address are added before the read command specification.

16. The read command format for the flash memory device of claim 14, wherein the special code is arranged before the read command code of the read command specification, and the column address is replaced by the final written word line address.

17. The read command format for the flash memory device of claim 14, wherein the read command format further comprises a first portion and a second portion,
the first portion comprises a prefix, the read command code, the column address, the final written word line address, and the special code in sequence, and
the second portion is the read command specification.

18. The read command format for the flash memory device of claim 14, wherein the read command format further comprises a set feature value portion,
the set feature value portion comprises a set feature command, a feature value, and the final written word line address in sequence.

19. The read command format for the flash memory device of claim 14, further comprising a prefix arranged before the special code.
